(19) United States
(12) Patent Application Publication
(10) Pub. No.: US 2015/0243428 A1
(43) Pub. Date: Aug. 27, 2015

(54) METHODS AND SYSTEMS OF FIELD UPGRADEABLE TRANSFORMERS

(71) Applicant: VARENTEC, INC., San Jose, CA (US)

(72) Inventors: Deepakraj M. Divan, San Jose, CA (US); Anish Prasai, San Jose, CA (US)

(73) Assignee: VARENTEC, INC., SAN JOSE, CA (US)

(21) Appl. No.: 14/187,114

(22) Filed: Feb. 21, 2014

(51) Int. Cl. H01F 27/02; H01F 27/12; H02M 1/00; G05F 1/14; H02M 5/12; H01F 27/04; G01R 1/20

(52) U.S. Cl. CPC H01F 27/025; H01F 27/04; H01F 27/12; G01R 1/20; G05F 1/14; H02M 5/12; H02M 1/00; H02M 2001/0006

(57) ABSTRACT

Methods and systems of field upgradeable transformers are provided. Voltage transformation, intelligence, communications, and control are integrated in a flexible and cost effective manner. A field upgradeable transformer may comprise a transformer module and a cold plate. The transformer module provides voltage transformation. The transformer module is enclosed in a housing containing coolant with dielectric properties, such as mineral oil. The cold plate may be mounted to the housing and thermally coupled to the coolant. Interfaces to the primary side and/or secondary side of transformer module may be configured to be disposed on the surface of the housing. A field upgradable transformer may comprise various electronic modules that are configured to be mounted to the cold plate. An electronic module may be thermally coupled to the coolant, and may be configured to be coupled to the transformer module. An electronic module may monitor the voltage level of the primary side and/or the secondary side of the field upgradeable transformer, the current level through the field upgradeable transformer, the power factor, and/or the coolant temperature; create an outage alert; communicate with a control center; provide electromechanical tap changing; regulate line voltages, power factor, and/or harmonics; and/or mitigate voltage sags.

### BACKGROUND

1. Field of the Invention(s)

The present invention(s) generally relate to power distribution grid network optimization strategies. More particularly, the invention(s) relate to systems and methods of network voltage regulating transformers.

2. Description of Related Art

A distribution transformer is a transformer that provides the final voltage transformation in an electric power distribution system. Distribution transformers step down the voltage from a distribution medium voltage level (typically 4-24 kV), to a lower voltage (120 to 480 volts), for use at customer homes and industrial/commercial facilities. Distribution transformers are ubiquitous, with an estimate of as many as 300 million deployed worldwide. The distribution transformers do not include electronics and lack control modules. As a result, the distribution transformers are economical and last for many (e.g., 30-50) years, and have no servicing requirements.

Being the hub of an electric power system, distribution transformers are important because they connect utility's customers to the grid. Nevertheless, distribution transformers do not include any monitoring modules and lack any control capabilities. Voltage on the customer side (i.e., the secondary side voltage) cannot be monitored and regulated in distribution transformers. Regulating voltage levels within an acceptable band mandated by a standard or by practice (like the ±5% ANSI band in the USA) can result in lower energy consumptions.

Voltage regulations on the secondary side of distribution transformers can be achieved by installations of tap changing transformers and continuously variable line voltage regulators. However, mechanical switches cannot provide fast responses and the operations for electromechanical switching schemes are limited. Inverters—or direct AC/AC converters—based solutions may also regulate voltage on the secondary side of the distribution transformers. Nevertheless, the power losses are high, and these solutions usually require fans or other active thermal management schemes that limit the overall life of the device. The power losses also detract from the reductions in power consumption that are gained by the customer. The basic mismatch between the low cost and long life of a distribution transformer, and the high cost and short life for controls and communications needed to deliver the improved value to the utility's customers remains a big challenge.

### SUMMARY OF THE INVENTION

Methods and systems of field upgradeable transformers are provided. Various embodiments may integrate voltage transformation, intelligence, communications, and control in a flexible and cost effective manner. Various embodiments comprise a transformer module and a cold plate. The transformer module provides voltage transformation. The transformer module is enclosed in a housing containing coolant with dielectric properties, such as mineral oil. The cold plate may be mounted to the housing and thermally coupled to the coolant. Interfaces (e.g., power connections) to the primary side and/or secondary side of transformer module may be disposed on the surface of the housing. In addition, various interfaces (e.g., a voltage measurement, a current measurement, a temperature measurement) may be configured to be disposed on the surface of the housing.

Further embodiments may comprise various electronic modules that are configured to be mounted to the cold plate. An electronic module may be thermally coupled to the coolant. An electronic module, when coupled to the cold plate, may exchange heat with the transformer module via the cold plate. The electronic module nevertheless does not significantly increase the heat load of the transformer module, thereby resulting in a minimal cost impact. Further, an electronic module may be configured to be coupled to the transformer module. An electronic module may monitor the voltage level of the primary side and/or the secondary side of the field upgradeable transformer, the current level through the field upgradeable transformer, the power factor, and/or the coolant temperature; create an outage alert; communicate with a control center; provide electromechanical tap changing; regulate line voltages, power factor, and/or harmonics; and/or mitigate voltage sags. In various embodiments, an electronic module and a transformer module may be enclosed in separate housings. The electronic module may be configured to be mountable to the cold plate.

### BRIEF DESCRIPTION OF THE DRAWINGS

FIG. 1A illustrate the mechanical packaging of an exemplary single-phase field upgradeable transformer in accordance with an embodiment.

FIG. 1B illustrates the electric circuit diagram of an exemplary single-phase field upgradeable transformer in accordance with an embodiment.

FIG. 2A illustrates the mechanical packaging of an exemplary single-phase field upgradeable transformer in accordance with an embodiment.

FIG. 2B illustrates the electric circuit diagram of an exemplary single-phase field upgradeable transformer in accordance with an embodiment.

FIG. 3 illustrates the electric circuit diagram of an exemplary single-phase field upgradeable transformer in accordance with an embodiment.

FIG. 4 illustrates the electric circuit diagram of the exemplary single-phase field upgradeable transformer in accordance with an embodiment.

FIG. 5 illustrates the electric circuit diagram of the exemplary single-phase field upgradeable transformer in accordance with an embodiment.

FIG. 6A illustrates the electric circuit diagram of the exemplary single-phase field upgradeable transformer in accordance with an embodiment.

FIG. 6B illustrates operation waveforms of an exemplary field upgradeable transformer in accordance with an embodiment.

FIG. 6C illustrates the electric circuit diagram of the exemplary single-phase field upgradeable transformer in accordance with an embodiment.

FIG. 7 illustrates an example computing module that may be used in implementing various features of embodiments of the present application.

### DETAILED DESCRIPTION OF THE INVENTION

Distribution transformers are cooled by using coolant with electrically insulating properties, such as mineral oil. The transformer core and windings are usually immersed in the coolant. The coolant may remove heat from the transformer, provide insulation, and suppress corona and arcing, such that the transformer may be smaller in size and lower in cost. When heated, the coolant (e.g., oil) may rise in the tank and create a circulatory flow in the tank. Fins may be used to improve heat transfer to the environment. Fins and radiators, through which the natural convection based flow of coolant completes, may be connected to the tank and realize a greater heat exchange area. As such, the distribution transformers can operate with high reliability and at a low cost for many years. On the other hand, compared with the distribution transformers, electronic devices such as sensors and converters, which may be used in conjunction with the distribution transformers, have a much shorter life, often limited by the life of the cooling systems with moving parts (e.g., fans and pumps), semiconductor devices, and electrolytic capacitors. In addition, electronics, communications standards, and utility requirements are changing rapidly. From time to time, electronic devices such as sensors are required to be replaced or upgraded. Accordingly, there is a mismatch between the life and cost of the distribution transformers and the electronics.

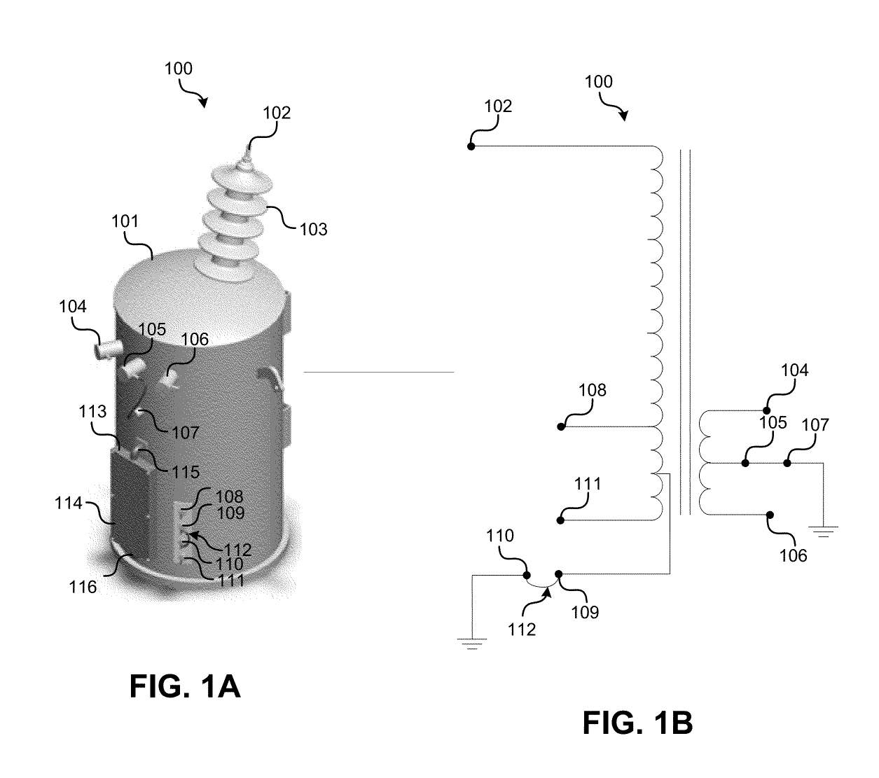

FIGS. 1A-1B illustrate an exemplary single-phase field upgradeable transformer 100 in accordance with an embodiment. FIG. 1A illustrates the mechanical packaging of the exemplary single-phase field upgradeable transformer 100 and FIG. 1B illustrates the electric circuit diagram of the exemplary single-phase field upgradeable transformer 100. The illustrated single-phase field upgradeable transformer 100 includes a housing 101 and a transformer module (not shown in FIG. 1A) having a transformer core and windings. The housing 101 encloses the transformer module. The housing 101 may contain coolant, in which the transformer core and the transformer windings are immersed. The field upgradeable transformer 100 comprises interfaces 102, 104-107, and 108-111, a cold plate 113, and conduits 115-116. The interfaces 102, 104-107, and 108-111 are configured to be disposed on the surface of the housing 101. In one embodiment, the interfaces 102, 104-107, and 108-111 are disposed on the surface of the housing 101. The cold plate may have a cover plate 114 that is removable. The cold plate 113 may be mounted to the housing 101. For example, in the illustrated example, the cold plate 113 is mounted to the surface of the housing 101. The cold plate 113 may be configured to be thermally coupled to the interior of the housing 101. The cold plate 113 may be a container in various shapes. In one embodiment, the cold plate 112 may be sealed. In another embodiment, the cold plate 113 may be configured such that, when coupled to the housing 101, the cold plate 113 and the surface of the housing 101 to which the cold plate 113 is coupled, may form a sealed and hollow chamber. In various embodiments, the conduits 115-116 are coupled to the housing 101 and to the cold plate 113. The conduits 115-116 provide a path for the coolant to flow thereby allowing heat exchange between the coolant and the cold plate. Accordingly, the cold plate 113 may be thermally coupled to the coolant contained in the housing 101 via the conduits 115-116. In various embodiments, the cold plate 113 is made of aluminum.

The interface 102 may be coupled to a first end of the primary windings of the field upgradeable transformer 100. Each of the interfaces 108-109 and 111 may be coupled to one tap of a set of taps of the primary windings of the field upgradeable transformer 100. In various embodiments, the interface 109 is coupled to the middle tap of the set of taps of the primary windings of the field upgradeable transformer 100. The interface 102 may be coupled to the interface 110 via a jumper 112. As such, the interface 110 may be grounded. The interfaces 108 and 111 may be coupled to +/−5% or +/−8% taps, with respect to the interface 109. That is, the voltage difference between the interface 109 and each of the interfaces 108 and 111, is +/−5% or +/−8% of the input voltage on the primary winding of the field upgradeable transformer 100. When the interface 109 is coupled to the interface 110 and the interface 110 is grounded, the electric potentials of the interfaces 108 and 111 are both close to zero. The interfaces 104-106, may be coupled to a first end, a second end, and a third end of the secondary windings, respectively, of the field upgradeable transformer 100. The interface 105 may be coupled to the center tap of the secondary windings of the field upgradeable transformer 100. The center tap 105 of the secondary windings of the field upgradeable transformer 100 may be coupled to protective-earth ground. In various embodiments, the protective-earth ground is the same as the housing 101.

The field upgradeable transformer 100 may further include cooling fins or radiators (not shown) coupled to the housing 101. The cooling fins or radiators may augment the heat transfer and provide a better cooling capability. In various embodiments, the field upgradeable transformer 100 may comprise electronic modules that monitor the voltage level, the current level, power level, the power factor, and/or the coolant temperature; communicate with a control center; provide electromechanical tap changing; regulate line voltages, power factor, and/or harmonics; and/or mitigate voltage sags; and with small amount of energy storage, provide outage alerts through detection and communication as part of a last gasp effort. Each of the electronic modules may be enclosed in a housing that is separate from the housing 101. In various embodiments, an electronic module may be configured to be mountable to the cold plate 113 and electrically coupled to one or more interfaces of the interfaces 108-111. As such, various embodiments, such as the field upgradeable transformer illustrated in FIGS. 1A-1B, may support any electronic modules. The electronic modules may be packaged with no cooling systems or other components that require field service and maintenance. The electronic modules may be mounted to the cold plate 113. Each of the electronic modules, when mounted to the cold plate 113, may be thermally coupled to the transformer module of the field upgradeable transformer 100. The cooling mechanism of the field upgradeable transformer 100 may be shared with the electronic modules. Heat generated by the electronic modules may be transferred to the coolant contained in the housing 101. The additional heat load introduced by the electronic modules is minimal and causes minimal cost impact.

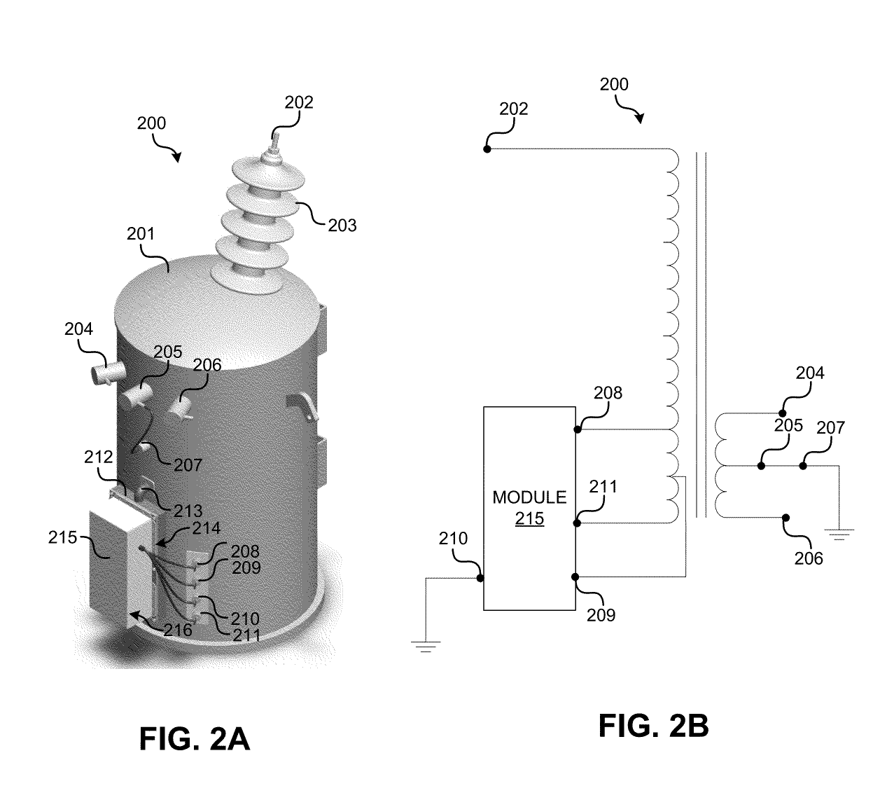

FIGS. 2A-2B illustrate an exemplary single-phase field upgradeable transformer 200 in accordance with an embodiment. FIG. 2A illustrates the mechanical packaging of the exemplary single-phase field upgradeable transformer 200 and FIG. 2B illustrates the electric circuit diagram of the exemplary single-phase field upgradeable transformer 200. The illustrated single-phase field upgradeable transformer 200 includes a housing 201 and a transformer module (not shown in FIG. 2A) having a transformer core and windings. The housing 201 encloses the transformer module. The housing 201 may contain coolant, in which the transformer core and the windings are immersed. The field upgradeable transformer 200 comprises interfaces 202, 204-207, and 208-211, a cold plate 212, a conduit 213, and an electronic module 215. The interfaces 202, 204-207, and 208-211 may be disposed on the surface of the housing 201. The cold plate 212 is mounted to the housing 201 and has a surface 214, on which the electronic module 215 may be mounted. The cold plate 212 may be mounted to the housing 201. For example, in the illustrated example, the cold plate 212 is mounted to the surface of the housing 201. The cold plate 212 may be configured to be thermally coupled to the interior of the housing 201. The cold plate 212 may be a container in various shapes. In one embodiment, the cold plate 212 may be sealed. In another embodiment, the cold plate 212 may be configured such that, when coupled to the housing 201, the cold plate 212 and the surface of the housing 201 to which the cold plate 113 is coupled, may form a sealed and hollow chamber. In various embodiments, the conduit 213 is coupled to the housing 201 and to the cold plate 212. The conduit 213 provides a path for the coolant to flow thereby allowing heat exchange between the coolant and the cold plate. The conduit 213 provides a path for the coolant to flow thereby allowing heat exchange between the coolant and the cold plate. Accordingly, the cold plate 212 may be thermally coupled to the coolant contained in the housing 201 via the conduit 213. In various embodiments, the cold plate 213 is made of aluminum. The electronic module 215 comprises various sub-modules which are enclosed in the housing 216, that is separate from the housing 201. In some embodiments, the electronic module 215 does not include any cooling systems or other components that require field service and maintenance. The electronic module 215 is mounted to the cold plate 212.

The interface 202 may be coupled to a first end of the primary windings (not shown), of the field upgradeable transformer 200. The interfaces 208-209 and 211 may be coupled to various taps on the primary windings of the field upgradeable transformer 200. The interface 211 may be coupled to the middle tap of the set of taps on the primary windings of the field upgradeable transformer 200. The interfaces 208 and 211 may be coupled to +/−5% or +/−8% taps. The interface 210 may be grounded. The electronic module 215 may be coupled to the interfaces 208-211 of the primary windings of the field upgradeable transformer 200. Accordingly, when the interface 210 is grounded, the electronic module 215 is biased to an electric potential that is close to zero potential (e.g., +/−5% or +/−8% of the line voltage to which the primary windings are coupled). As such, the electronic module 215 has a low Basic Insulation Level (“BIL”) because the electronic module 215 is biased to a low voltage (e.g., the voltage difference between the taps across which the electronic module 215 is coupled). The electronic module 215 is also subject to a small current, that is the current through the primary windings of the field upgradeable transformer 200. Accordingly, various components of the electronic module are subject to a small voltage (e.g., the voltage difference between the taps across which the electronic module 215 is coupled) and a small current (e.g., the current through the primary windings of the field upgradeable transformer.)

In further embodiments, the electronic module 215 may be coupled to the secondary windings of the field upgradeable transformer 200. The interfaces 204-206 may be coupled to a first end, a second end, and a third end of the secondary windings, respectively, of the field upgradeable transformer 200. The interface 205 may be coupled to the center tap of the secondary windings of the field upgradeable transformer 200. In the illustrated example, the interface 205 is coupled to the neutral wire 207 of the field upgradeable transformer 200. That is, the center tap 205 of the secondary windings of the field upgradeable transformer 200 is “grounded” to the housing 201.

The field upgradeable transformer 200 may further include cooling fins (not shown) coupled to the housing 201. The distance between the cooling fins and the housing 201 may augment the heat transfer and provide a better cooling capability. In various embodiments, the electronic module 215 may comprise one or more sub-modules that monitor the voltage level, the current level, the power factor, the outage alert, and/or the coolant temperature; communicate with a control center; provide electromechanical tap changing; regulate line voltages, power factor, and/or harmonics; and/or mitigate voltage sags. In the illustrated example, the electronic module 215 is mounted to the cold plate 212. The electronic module 215 may be mounted to the surface 214 of the cold plate 212 by using screws, clamps, or other similar means. The electronic module 215 is thermally coupled to the cold plate. The cold plate 212, by exchanging heat with the coolant contained in the housing 201, facilitates cooling of the electronic module 215. Heat generated by the electronic module 215 may be transferred to the coolant contained in the housing 201. The additional heat load introduced by the electronic modules is minimal and causes minimal cost impact. On the other hand, if the losses are significant, the transformer design can be adapted to manage the excess losses.

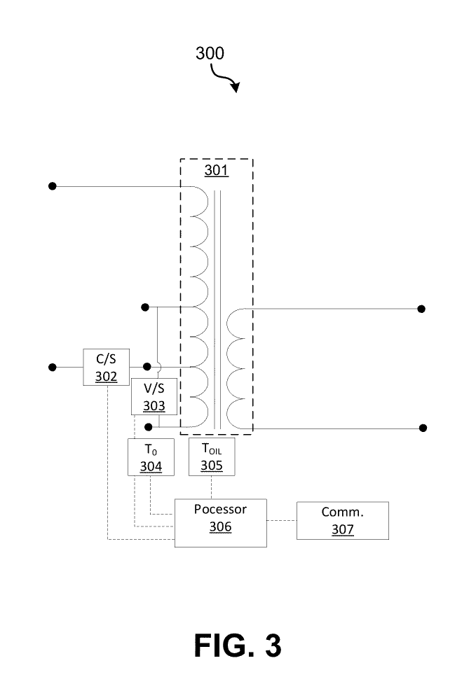

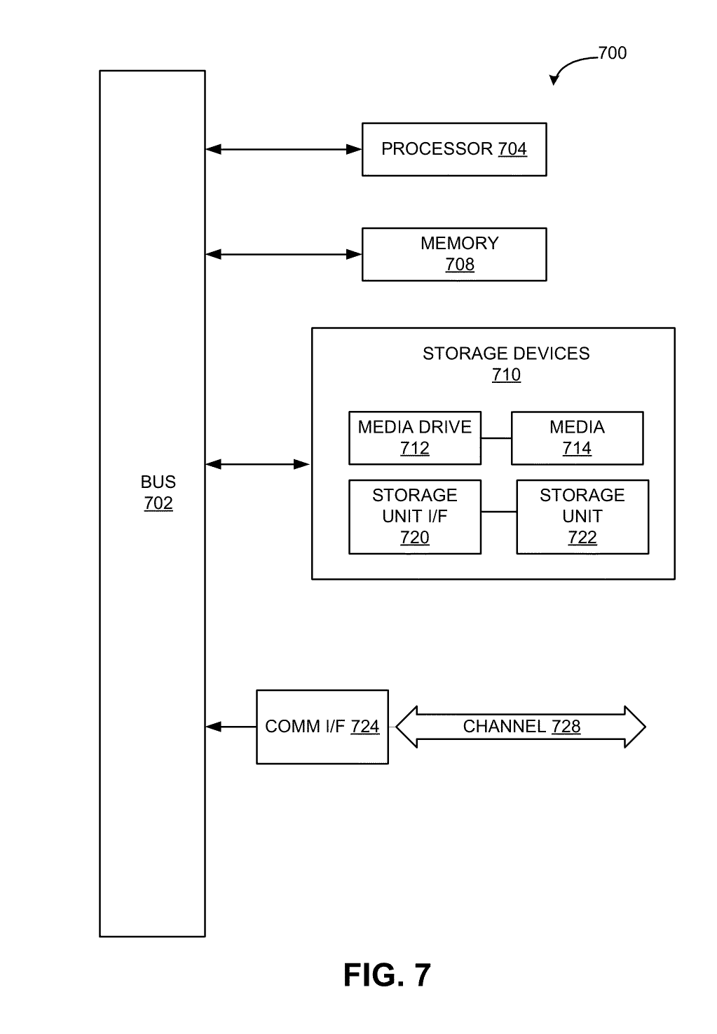

FIG. 3 illustrates the electric circuit diagram of the exemplary single-phase field upgradeable transformer 300. The illustrated single-phase filed upgradeable transformer 300 comprises a transformer module 301 including a transformer core and windings, and a current sensor 302, a voltage sensor 303, a temperature sensor 304, a temperature sensor 305, a processing module 306, and a communication module 307. The current sensor 302, the voltage sensor 303, the temperature sensor 304, the temperature sensor 305, the processing module 306, and the communication module 307 may be enclosed into one package. The current sensor 302 and the voltage sensor 303 measure the current through and the voltage of the primary side of the transformer module 301, respectively. The temperature sensor 304 measures the ambient temperature of the field upgradeable transformer 300, and the temperature sensor 305 measures the temperature of the coolant of the field upgradeable transformer 300. Each of the current sensor 302, the voltage sensor 303, the temperature sensor 304, and the temperature sensor 305 may transmit their respective measurement to the processing module 306. The processing module 306 may be implemented by an example computing module as illustrated in FIG. 7.

The processing module 306 may determine the instantaneous active power consumption, the energy consumption over a period of time, the power factor, the loading of the transformer core based on one or more measurements received from the current sensor 302, the voltage sensor 303, the temperature sensor 304, and the temperature sensor 305. The processing module 306 may further generate outage alert, historical data, diagnostics, and/or prognostics.

In the illustrated example, the primary side voltage is measured by the voltage sensor 303, which is placed across the taps of the primary windings of the transformer 301 to measure the voltage \vec{V}ₛₑₙₛₑ across the taps of the primary windings of the transformer. The primary side current is measured directly by the current sensor 302, \vec{I}=\vec{I}ₛₑₙₛₑ. The primary winding voltage may be determined to according to Equation (1):

V=k\vec{V}ₛₑₙₛₑ+\vec{I}ₛₑₙₛₑ\vec{Z}₁, (1)

where k is the ratio of the winding turns of the full primary winding to the winding turns across the taps where the sensor is connected and Z₁=R₁+iX₁ is the impedance of the primary winding across which voltage is dropped due to flow of current, I.

The instantaneous apparent S and real power P going into the transformer 301 are given by Equations (2) and (3), respectively:

S=\vec{V}·\vec{I} (2),

P=|S|cos(φ) (3),

where φ is the phase angle difference between the voltage, \vec{V}, and the current, \vec{I}.

The power factor PF is then assessed according to Equation (4):

$$PF = \frac{P}{S} , \qquad ( 4 )$$

where P is the instantaneous real power, and S is the instantaneous apparent power going into the transformer 301.

In some embodiments, the voltage sensor 303 may be placed across taps on the secondary side of the transformer 301 with the number of turns n₂, where the total number of winding turns on the primary winding is n₁, and the impedance of the primary to secondary winding is given by Z₂=R2+iX₂, then the voltage applied across the primary side can be determined according to Equation (5):

$$V = \frac{{n}_{1}}{{n}_{2}} {\vec{V}}_{sense} + {\vec{I}}_{sense} {\vec{Z}}_{2} . \qquad ( 5 )$$

Because transformers are typically rated for handling a certain amount of power, by monitoring the apparent power, S, the loading level of a transformer can be assessed in real time. In one embodiment, the Root Mean Square (“RMS”) current measurement by the current sensor 302 may be compared to a predetermined value (e.g., the transformer full current value) to determine the loading level of the transformer. For example, if the transformer full current is 100 A, and the RMS current measurement is 90 A, then the loading of the transformer is 90%. This provides valuable information that can be used to monitor the peak loading of a transformer and determine when new upgrades need to be made or how much stresses are being imposed on the distribution equipment.

In addition, by monitoring the power factor, PF, of the field upgradeable transformer 300, various embodiments ensure an accurate assessment of the energy consumption of the user. Accordingly, various embodiments enable the utility to accurately assess energy consumption of different customers. Measurements of the voltage and current also enable detailed assessment of both the power quality of the grid and the “dirtiness” of the load. The grid voltage measurement allows real-time feedback of continuity of service (power outages), voltage sags and swells that can trip or interrupt sensitive loads, transients voltages such as in a lightning storm or equipment switching upstream that can be damaging to loads, voltage harmonics that can incite losses on the system and cause distribution equipment and load to malfunction, etc.

In one embodiment, the RMS current measurement by the current sensor 302 or the RMS voltage measurement by the voltage sensor 303 may be compared to a predetermined value (e.g., zero), and if the current measurement or the voltage measurement is determined to be close to zero, then an outage alert is generated. Adequate energy storage is included in the module to provide the capability to detect an outage and transmit it through the communication module once the power outage has occurred. In one embodiment, the temperature measurement by the temperature sensor 304 may be compared to a predetermined value (e.g., the maximum operating ambient temperature of the field upgradeable transformer), and if the temperature measurement is above the predetermined value, a warning may be generated. The communication module 307 may transmit or receive signals from a grid control center or other devices. For example, the communication module 307 may transmit one or more measurements by the current sensor 302, the voltage sensor 303, the temperature sensor 304, and the temperature sensor 305, and/or one or more determinations based on the measurements to a grid control center, and/or receive instruction signals from the grid control center or another device.

The power factor PF may further be used to determine the load type. The measurement of field upgradable transformer 300 (or the load coupled to the field upgradeable transformer 300) current can provide valuable information as to the types of load coupled to the transformer 300, the harmonics, and the loading level. During any fault, the current measurement at each node can be used to determine the fault location or faulted load. Harmonic levels, measured as Total Harmonic Distortion (“THD”) or amplitude at each harmonic frequency, can be used to assess whether the loads are in compliance with IEEE 519. Transformers can in turn be de-rated or sized accordingly, due to greater losses from increased harmonics, to maintain long life. In addition to the power factor PF, the field upgradeable transformer 300 may further determine power quality indices, such as THD, telephone influence factor, C message index, transformer de-rating factor or K factor, crest factor, unbalance factor, or flicker factor may be determined by the processing module 306. As such, these indices at each of the nodes on which the FUT 301 are installed may be assessed by the utility.

With distributed energy resources (e.g., rooftop photovoltaics (“PV”)) becoming more popular, the current measurement provided by the current sensor 302 may also reveal when power starts to reverse and flow back into the grid. Further, the ability to monitor instantaneous power and energy consumption also enables advanced functionality such as energy theft detection, an issue that is faced by many utilities. Various embodiments including sensors of high enough accuracy class have energy metering functionality.

In various embodiments, the processing module 306 may further evaluate the life of the transformer module 301 by using the measurements provided by the voltage sensor 303, the current sensor 302, and/or the temperature sensors 304-305. The life of a transformer depends on insulation degradation, which is a function of the winding temperature. The winding temperature, in turn, is a cumulative function of transformer losses, which vary with loading. The total load loss is given in Equation Error! Reference source not found.:

P_{LL}=P+P_{EC}±P_{OSL} (6),

where P_{LL} is the total load loss, P is the I²R loss due to the transformer impedance, P_{EC} is the winding eddy current loss, and P_{OSL} is the other stray loss.

The total loss P_{LL}, the winding eddy current loss P_{EC}, and the other stray loss P_{OSL} may be determined according to the Equations (7)-(9), respectively:

$$\begin{matrix}{P}_{EC} = {P}_{EC - R} {\sum }_{h = 1}^{n} {( \frac{{I}_{h}}{I} )}^{2} {h}^{2} , & ( 7 ) \\ {P}_{OSL} = {P}_{OSL - R} {\sum }_{h = 1}^{n} {( \frac{{I}_{h}}{I} )}^{2} {h}^{0.8} , & ( 8 ) \\ {P}_{LL} = R * \sum {I}_{h}^{2} + {P}_{EC} + {P}_{OSL} , & ( 9 )\end{matrix}$$

where P_{EC-R} is the Rated Eddy current losses, h is the Harmonic order, Iₕ is the harmonic current of order h, and I is the total RMS current.

The winding temperature is the main factor determining the life of a transformer. The winding temperature causes insulation degradation and accelerating loss of life. The temperature is not uniform throughout the winding and insulation failure would most probably occur at the hottest point. The processing module may determine the absolute temperature of the winding hot spot based on the ambient temperature (e.g., the temperature measured by the temperature sensor 304) and the coolant temperature (e.g., the temperature measured by the temperature sensor 305). Given the rated values, the temperatures can be determined at all loadings according to Equations (10)-(11) below. The temperature is proportional to losses by an exponential factor. In various embodiments, the exponents are assumed to be 0.8.

$$\begin{matrix}Δ {θ}_{TO} = Δ {{θ}_{TO - R} ( \frac{{P}_{LL} + {P}_{NL}}{{P}_{LL - R} + {P}_{NL}} )}^{n} ° C . , & ( 10 ) \\ Δ {θ}_{HS} = Δ {{θ}_{HS - R} ( \frac{{P}_{LL}}{{P}_{LL - R}} )}^{m} ° C . , & ( 11 )\end{matrix}$$

where Δθ_{TO} is the top cooling temperature rise over ambient, Δθ_{TO-R} is the rated top coolant temperature rise over ambient, Δθ_{HS} is the hot spot temperature rise over top coolant temperature, Δθ_{Hs-R} is the rated hot spot temperature rise over top coolant temperature, P_{LL} is the load loss, P_{LL-R} is the rated load loss, P_{NL} is the no-load loss, and n and m are empirical constants.

In some embodiments, the transformer thermal conductivity may be nonlinear, the hot spot and the coolant temperature may be determinedly dynamically according to Equations (12)-(13), respectively:

$$\begin{matrix} {T}_{TO} \frac{d {θ}_{TO}}{d t} = ( \frac{{P}_{LL} + {P}_{NL}}{{P}_{LL - R} + {P}_{NL}} ) * {( Δ {θ}_{TO - R} )}^{( 1 / n )} - {( Δ {θ}_{TO} )}^{( 1 / n )} , & ( 12 ) \\ {T}_{HS} \frac{d {θ}_{HS}}{d t} = ( \sum {I}_{h}^{2} ( 1 + {h}^{2} * {P}_{EC - R} ) ) * {( Δ {θ}_{HS - R} )}^{( 1 / m )} - {( Δ {θ}_{HS} )}^{( 1 / m )} , & ( 13 )\end{matrix}$$

where θ_{W} is the top coolant temperature, θ_{HS} is the hot spot temperature, Δθ_{TO-R} is the rated top coolant temperature rise over ambient, Δθ_{HS-R} is the rated hot spot temperature rise over top coolant temperature, T_{TO} is the thermal time constant for top coolant, T_{HS} is the thermal time constant for winding hot spot, P_{LL} is the load loss, P_{LL-R} is the rated load loss, P_{NL} is the no-load loss, P_{EC-R} is rated Eddy current losses, and n and m are empirical constants.

The processing module 306 may determine the life of the transformer module 301 by the life of the insulation which is rated on the basis of average winding temperature rise. Two types of insulation systems are typically used: 55° C. rise and 65° C. rise. The reference hottest spot temperature is 110° C. for 65° C. average winding rise and 95° C. for 55° C. average winding rise transformers. The processing module 306 may determine an aging acceleration factor (F_{AA}) that determines the rate of insulation deterioration for a given hot spot temperature. The aging acceleration factor for a 65° C. rise insulation system may be determined according to Equation (14). For winding hot spot temperatures greater than the reference temperature 110° C., F_{AA} has a value that is greater than one. For winding hot spot temperatures below 110° C., F_{AA} has a value that is less than one.

$${F}_{AA} = exp ( \frac{15000}{383} - \frac{15000}{{θ}_{HS} + 273} ) per unit , \qquad ( 14 )$$

where θ_{HS} is the hot spot temperature, and F_{AA} is the aging acceleration factor.

Transformer Loss of Life (LoL) over a period is determined by the average value of acceleration factor over that period according to Equation (15).

LoL=1/T∫F_{AA}dt per unit (15),

where LoL is the hot spot temperature, and F_{AA} is aging acceleration factor.

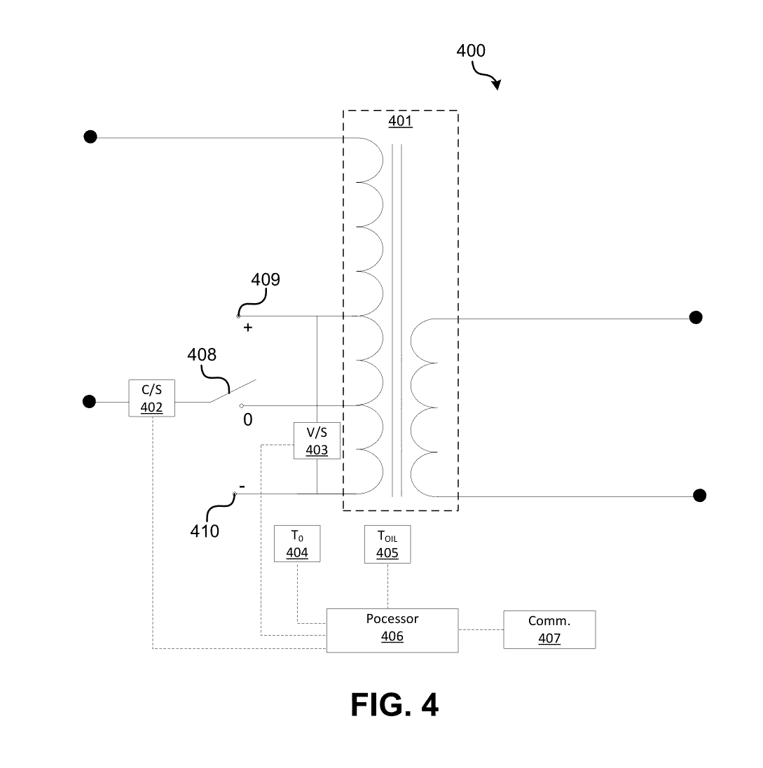

FIG. 4 illustrates the electric circuit diagram of the exemplary single-phase field upgradeable transformer 400. The illustrated single-phase filed upgradeable transformer 400 comprises a transformer module 401, a current sensor 402, a voltage sensor 403, a temperature sensor 404, a temperature sensor 405, a processing module 406, a communication module 407, and a switching element 408. The current sensor 402, the voltage sensor 403, the temperature sensor 404, the temperature sensor 405, the processing module 406, the communication module 407, and the switching element 408 may be enclosed in one housing. The current sensor 402 measures the current through the primary side of the transformer module 401, and the voltage sensor 403 measures the voltage of the primary side of the transformer 401. The temperature sensor 404 measures the ambient temperature of the field upgradeable transformer 400, and the temperature sensor 405 measures the temperature of the coolant of the field upgradeable transformer 400. The switching element 408 may be an electromechanical relay or a contactor in parallel with a semiconductor-based AC switch (e.g., a thyristor pair), or a semiconductor-based AC switch (e.g., a thyristor pair). When a electromechanical relay or a contractor is in parallel with a semiconductor-based AC switch, the semiconductor-based AC switch may ensure the voltage across the electromechanical relay or the contractor is under zero thereby reducing stresses on the electromechanical relay or the contractor during turn-on and turn-off. The switching element 408 may be coupled to either the top (409) or bottom (410) tap of the field upgradeable transformer 400 such that the voltage on the secondary side may be adjusted discretely (e.g., +/−5% or +/−8% depending on the size of the tap). One of ordinary skill in the art will understand that the field upgradeable transformer 400 may comprise a set of taps on the primary winding and the switching element 408 may be switched to be coupled to one tap of the set of taps. In one embodiment, the voltage measurement by the voltage sensor 403 may be compared to a set of predetermined values (e.g., a set of voltage set points), and if the voltage measurement is determined to be outside the range of the predetermine values, a voltage value may be determined from the set of predetermined values. A switching instruction may be determined based on the voltage value.

Each of the current sensor 402, the voltage sensor 403, the temperature sensor 404, and the temperature sensor 405 may transmit their respective measurement to the processing module 406. The processing module 406 may determine the instantaneous active power consumption, the energy consumption over a period of time, the power factor, the loading of the transformer core based on one or more measurements received from the current sensor 402, the voltage sensor 403, the temperature sensor 404, and/or the temperature sensor 405. The processing module 406 may further generate switching signals to regulate the switching of the switching element 408 based on a predetermined voltage range. The processing module 406 may further generate outage alerts, historical data, diagnostics, and/or prognostics. The communication module 407 may transmit or receive signals from a grid control center or other devices. The communication module 407 may receive commands from a grid operator, and the processing module may generate switching signals to control the switching element 408 based on the commands.

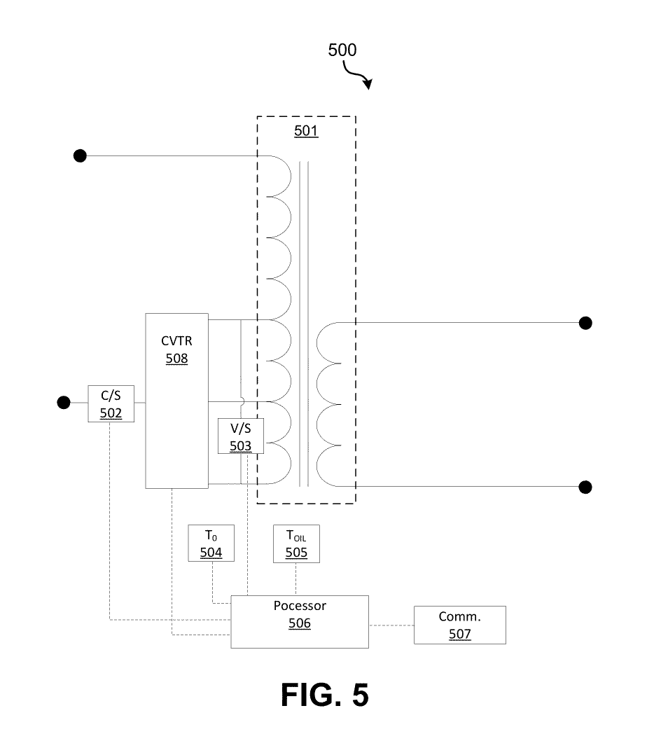

FIG. 5 illustrates the electric circuit diagram of the exemplary single-phase field upgradeable transformer 500. The illustrated single-phase filed upgradeable transformer 500 comprises a transformer module 501, a current sensor 502, a voltage sensor 503, a temperature sensor 504, a temperature sensor 505, a processing module 506, a communication module 507, and a converter 508. The current sensor 502, the voltage sensor 503, the temperature sensor 504, the temperature sensor 505, the processing module 506, the communication module 507, and the converter 508 may be enclosed by one housing. The current sensor 502 measures the current through the primary side of the transformer core 501, and the voltage sensor 503 measures the voltage of the primary side of the transformer 501. The temperature sensor 504 measures the ambient temperature of the field upgradeable transformer 500, and the temperature sensor 505 measures the temperature of the coolant of the field upgradeable transformer 500. The converter 508 may be coupled to a set of taps of the field upgradeable transformer 500 such that the voltage may be adjusted dynamically within the plus/minus band (e.g., +/−5% or +/−8%). As such, the converter 508 has low Basic Insulation Level (“BIL”) because the converter 508 is biased to a low voltage (e.g., the voltage difference between the taps across which the converter 508 is coupled). The converter 508 is also subject to a small current, that is the current through the primary windings of the field upgradeable transformer 500. Accordingly, various components of the electronic module are subject to a small voltage (e.g., the voltage difference between the taps across which the electronic module 508 is coupled) and a small current (e.g., the current through the primary windings of the field upgradeable transformer 500.)

Each of the current sensor 502, the voltage sensor 503, the temperature sensor 504, and the temperature sensor 505 may transmit their respective measurement to the processing module 506. The processing module 506 may determine the instantaneous active power consumption, the energy consumption over a period of time, the power factor, the loading of the transformer core based on one or more measurements received from the current sensor 502, the voltage sensor 503, the temperature sensor 504, and the temperature sensor 505. The processing module 506 may further generate switching signals to regulate the switching of the switching element 508 based on a predetermined voltage range. The processing module 506 may further generate outage alert, historical data, diagnostics, and/or prognostics. The communication module 407 may transmit or receive signals from a grid control center or other devices. The communication module 507 may receive commands from a grid operator, and the processing module may generate switching signals to control the switching element 508 based on the commands.

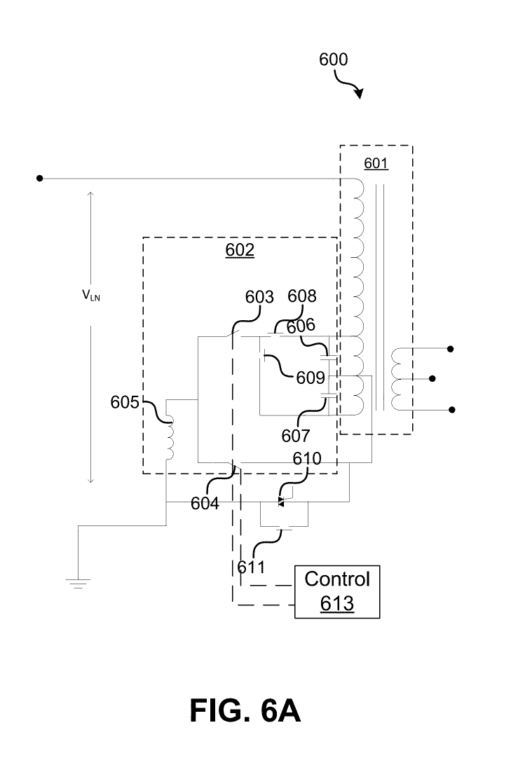

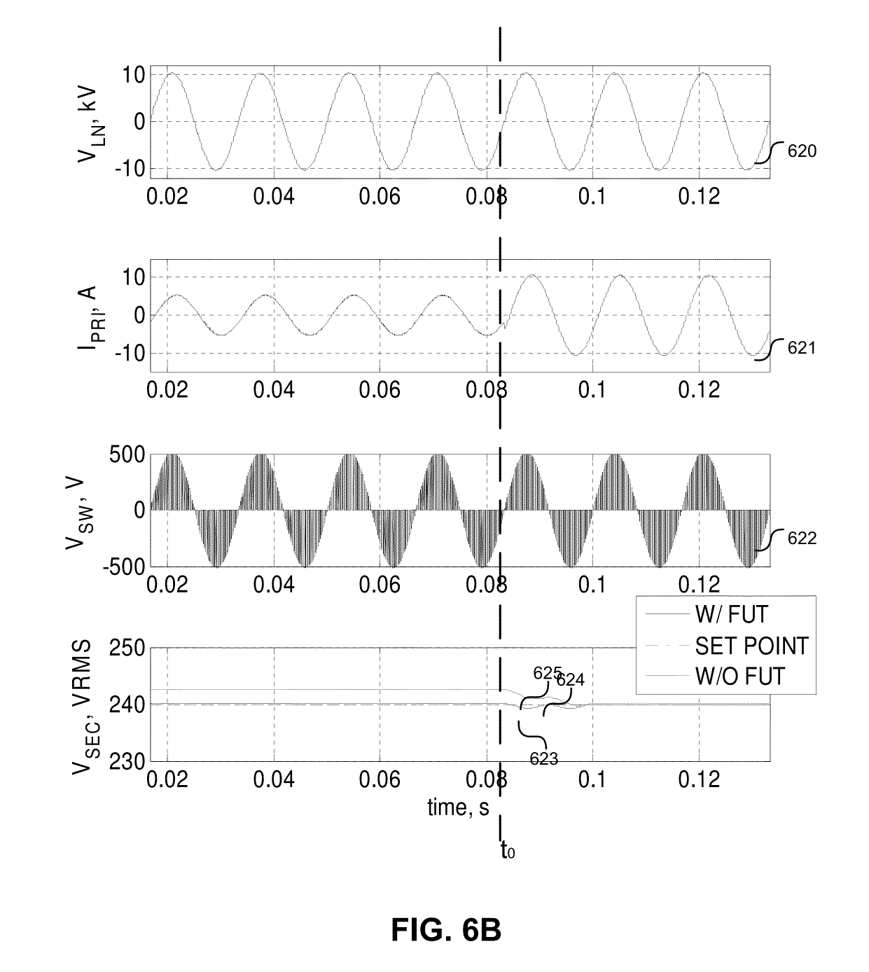

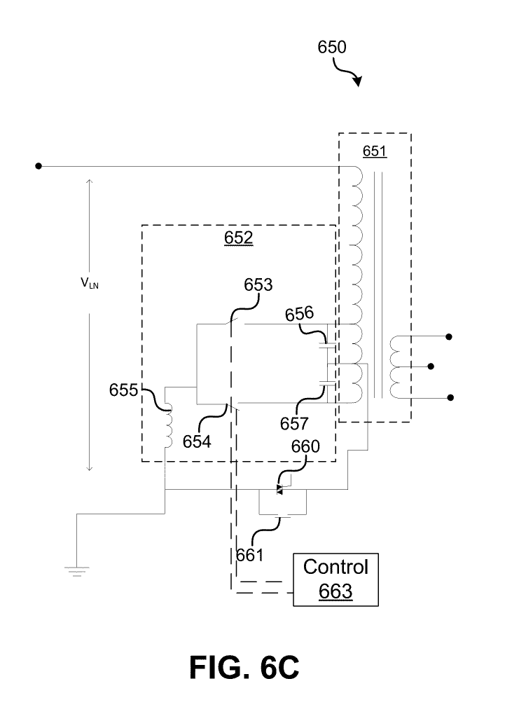

FIG. 6A illustrates the electric circuit diagram of the exemplary single-phase field upgradeable transformer 600. The illustrated field upgradeable transformer 600 comprises a transformer module 601 and a converter 602. The converter 602 comprises switches 603-604, an inductor 605, capacitors 606-607, and switches 608-609. The converter 602 is across the taps of the primary winding of the transformer module 601 and biased with respect to the ground. As such, the converter 602 has low Basic Insulation Level (“BIL”) because the converter 602 is biased to a low voltage (e.g., the voltage difference between the taps across which converter 602 is coupled). The converter 602 is also subject to a small current, that is the current through the primary windings of the field upgradeable transformer 600. Accordingly, various components of the electronic module are subject to a small voltage (e.g., the voltage difference between the taps across which the converter 602 is coupled) and a small current (e.g., the current through the primary windings of the field upgradeable transformer 600.)

The field upgradeable transformer 600 may further comprise a fail-normal switch comprising a thyristor-pair 610 and an electromechanical switch 611. The fail-normal switch switches to bypass the converter 602 when the converter fails or when there is a fault downstream. Accordingly, the middle tap of the set of taps of the primary winding of the transformer module 601 is ensured to be grounded via the fail-normal switch. The switches 603-604 may be semiconductor based AC switches. In various embodiments, each of the AC switches 603 and 604 is a pair of IGBTs that are either common-emitter and/or common-collector connected. The converter 602 is coupled across the taps of the primary side of the transformer core 601. The voltage applied across the primary side of the transformer, and in turn the secondary side voltage, may be regulated by the converter 602. The switches 608-609 may be electromechanical or semiconductor switches. The switches 608-609 may be configured to operate such that the field upgradable transformer 600 may operate in either a buck mode (e.g., when the voltage is too high) or a boost mode (e.g., when the voltage is too low).

In various embodiments, the converter 602 may monitor the temperature of the coolant and/or cold plate of the field upgradeable transformer 600. A warning may be generated upon determining an occurrence of an over temperature and the operation of converter 602 may be temporarily disabled. The fail-normal switch provides protection to the field upgradeable transformer 600. For instance, when one of the switches 603-604 fails, the relay 611 may bypass the converter 602 and ensure uninterrupted operation of the field upgradeable transformer 600. The converter 602 may be replaced without interrupting the operation of the transformer module 601 as the converter 602 and the transformer module 601 are enclosed by different housings. This level of redundancy offers high levels of reliability even as the transformer performance is augmented. The field upgradeable transformer 600 may further comprise a control module 613 regulating switching of the switches 603-604 of the converter 602. The control module 613 may be implemented by an example computing module as illustrated in FIG. 7. Duty cycle control of the converter 602 and Virtual Quadrature Source (described in the U.S. Pat. No. 8,179,702, entitled “Voltage Synthesis Using Virtual Quadrature Sources”) regulation may be implemented by the control module to achieve functions such as secondary side voltage control, power demand minimization, fast response to voltage sags, VAR injection and 3^{rd} harmonic management.

FIG. 6B illustrates operation waveforms of an exemplary field upgradeable transformer in accordance with an embodiment, such as the field upgradeable transformer 600 illustrated in FIG. 6A. The field upgradeable transformer operates in a buck mode. That is, the converter (e.g., the converter 602) included in the field upgradeable transformer has a buck converter configuration. Waveform 620 illustrates the grid voltage. Waveform 621 illustrates the current through the primary winding of the field upgradeable transformer. Waveform 622 illustrates the voltage across the converter switch (e.g., the switches 603-604). Waveform 623 illustrates the voltage across the secondary winding of the field upgradeable transformer, waveform 624 illustrates the voltage set point, and waveform 625 illustrates the voltage of the transmission line to which the secondary winding of the field upgradeable transformer is coupled, when the field upgradeable transformer is disconnected.

FIG. 6C illustrates the electric circuit diagram of the exemplary single-phase field upgradeable transformer 650. The illustrated field upgradeable transformer 650 comprises a transformer module 651 and a converter 652. The converter 652 comprises semiconductor based AC switches 653-654, an inductor 655, and capacitors 656-657. The field upgradeable transformer 650 may further comprise a fail-normal switch comprising a thyristor-pair 660 and an electromechanical switch 661. The fail-normal switch switches to bypass the converter 652 when the converter fails or when there is a fault downstream. In various embodiments, each of the AC switches 653 and 654 is a pair of IGBTs that are either common-emitter and/or common-collector connected. The converter 652 is coupled across the taps of the primary side of the transformer core 651. The voltage applied across the primary side of the transformer, and in turn the secondary side voltage, may be regulated by the converter 652. Compared with the embodiment illustrated in FIG. 6A, the voltages handled by the switches 653 and 654 are twice the voltages handled by the switches 603 and 604. But the embodiment illustrated in 6B requires less number of switches.

In various embodiments, the converter 652 may monitor the temperature of the coolant and/or cold plate of the field upgradeable transformer 650. A warning may be generated upon determining an occurrence of an over temperature and the operation of converter 652 may be temporarily disabled. The fail-normal switch provides protection to the field upgradeable transformer 650. For instance, when one of the switches 653-654 fails, the relay 661 may bypass the converter 652 and ensure an uninterrupted operation of the field upgradeable transformer 650. The converter 652 may be replaced without interrupting the operation of the transformer module 651 as the converter 652 and the transformer module 651 are enclosed by different housings. This level of redundancy offers high levels of reliability even as the transformer performance is augmented. The field upgradeable transformer 650 may further comprise a control module (not shown) regulating switching of the switches 653-654 of the converter. The control module 663 may be implemented by an example computing module as illustrated in FIG. 7. Duty cycle control of the converter 652 and Virtual Quadrature Source (described in the U.S. Pat. No. 8,179,702, entitled “Voltage Synthesis Using Virtual Quadrature Sources”) regulation may be implemented by the control module to achieve functions such as secondary side voltage control, power demand minimization, fast response to voltage sags, VAR injection and 3^{rd} harmonic management.

The converter shown in FIGS. 6A and 6C are single-phase direct AC converters. The AC-AC converter may operate by control of the duty cycle where the duty is constant in a steady-state. For example, in FIG. 6A, when the switch 608 is on and switch 609 is off, the field upgradeable transformer 600 operates in a boost mode. The switches 603 and 604 may be modulated using high-frequency synthesis to impose a certain voltage across the primary winding of the field upgradeable transformer 600. With respect to the common point of capacitors 606 and 609, the voltage across the primary winding of the field upgradeable transformer under the boost mode may be expressed as:

$${V}_{PRI} = [ 1 + \frac{{k}_{1}}{{n}_{1} - {k}_{1}} D ] {V}_{LN} , \qquad ( 16 )$$

where V_{LN} is the voltage applied across the primary winding of the field upgradable transformer, k₁ is the number of turns across the capacitor 606, n₁ is the number of turns from the top of the transformer to the midpoint of the capacitors 606 and 609, and D is the duty cycle of the switch 603.

Similarly, when the switch 608 is off and 609 is on, the field upgradeable transformer 600 operates in a buck mode. The voltage applied across the primary winding of the field upgradeable transformer under the buck mode may be expressed as:

$${V}_{PRI} = [ 1 - \frac{{k}_{2}}{{n}_{1} + {k}_{2}} D ] {V}_{LN} , \qquad ( 17 )$$

where k₂ is the number of turns of the winding across the capacitor 606. If the total number of turns across the secondary of the transformer is n₂, then the open-circuit voltage across the secondary winding of the field upgradeable transformer is expressed as:

$${V}_{SEC} = \frac{{n}_{2}}{{n}_{1}} {V}_{PRI} . \qquad ( 18 )$$

With voltage feedback, the duty cycle of switches 603 and 604 may be adjusted, in coordination with buck versus boost mode selection, to regulate the voltage of the transmission line to which the secondary winding of the field upgradeable transformer is coupled to a predetermined level. The duty cycle, D, may be modulated with sinusoidal expression according to VQS in accordance with Equation (19):

D=K₀+K₂ sin(2ωt+φ₂) (19).

The duty cycle D is a function of a constant term, K₀, and a second harmonic term of the fundamental frequency, ω, described by an amplitude of K₂, and phase angle φ₂. The resulting the voltage across the primary winding of the field upgradeable transformer is a function of the fundamental term ω and a third harmonic term 3ω with tunable amplitude and phase.

For example, when a field upgradeable transformer operates in the buck mode, according to the Equation (17), the voltage applied across the primary winding of the field upgradeable transformer may be expressed as:

$${V}_{PRI} = \underbrace{[ 1 - \frac{{k}_{2}}{{n}_{1} + {k}_{2}} {K}_{0} ] {V}_{m} sin ( ω t ) - \frac{{k}_{2}}{{n}_{1} + {k}_{2}} {K}_{2} {V}_{m} cos ( ω t + {φ}_{2} )}_{Fundamental Term} + \underbrace{\frac{{k}_{2}}{{n}_{1} + {k}_{2}} {K}_{2} {V}_{m} cos ( 3 ω t + {φ}_{2} )}_{Third harmonic term} , \qquad ( 20 )$$

where the source voltage across the primary winding is V_{LN}=Vₘ sin(ωt). The third harmonic term, by modulating K₂ and φ₂, may be used to de-couple some degree of third harmonic between the source and the load. The second harmonic term also has an impact on the fundamental term, per the above expression; therefore, K₀ may be used to regulate the fundamental term and counteract influences caused by the second harmonic term. Additional even harmonic terms may be introduced in the duty cycle illustrated in (19) to regulate higher order harmonics (e.g., 5th, 7th, 9th, or higher orders).

With respect to FIG. 6C, the voltage across the primary winding of the field upgradeable transformer 650, with respect to the midpoint of the capacitors 656 and 657 may be expressed as:

$${V}_{PRI} = ⌊ \frac{2 {n}_{1} k}{{n}_{1}^{2} - {k}^{2}} D + \frac{{n}_{1}}{{n}_{1} + k} ⌋ {V}_{LN} , \qquad ( 21 )$$

where the number of turns of the respective transformer winding across the capacitor 656 and 657 are equal: k=k₁=k₂. VQS regulation may be applied to result in generation of harmonic voltages that can be used to provide harmonic isolation or de-coupling functionality. The secondary side voltage may be given by Equation (18).

One ordinary skill in the art will understand that the single-phase configurations described herein are for illustration purposes. Various embodiments may have three-phase or split single-phase configurations.

As used herein, the term module might describe a given unit of functionality that can be performed in accordance with one or more embodiments of the present invention. As used herein, a module might be implemented utilizing any form of hardware, software, or a combination thereof. For example, one or more processors, controllers, ASICs, PLAs, PALs, CPLDs, FPGAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

Where components or modules of the invention are implemented in whole or in part using software, in one embodiment, these software elements can be implemented to operate with a computing or processing module capable of carrying out the functionality described with respect thereto. One such example computing module is shown in FIG. 8. Various embodiments are described in terms of this example-computing module 800. After reading this description, it will become apparent to a person skilled in the relevant art how to implement the invention using other computing modules or architectures.

Referring now to FIG. 7, computing module 700 may represent, for example, computing or processing capabilities found within desktop, laptop and notebook computers; hand-held computing devices (PDA's, smart phones, cell phones, palmtops, etc.); mainframes, supercomputers, workstations or servers; or any other type of special-purpose or general-purpose computing devices as may be desirable or appropriate for a given application or environment. Computing module 700 might also represent computing capabilities embedded within or otherwise available to a given device. For example, a computing module might be found in other electronic devices such as, for example, digital cameras, navigation systems, cellular telephones, portable computing devices, modems, routers, WAPs, terminals and other electronic devices that might include some form of processing capability.

Computing module 700 might include, for example, one or more processors, controllers, control modules, or other processing devices, such as a processor 704. Processor 704 might be implemented using a general-purpose or special-purpose processing engine such as, for example, a microprocessor, controller, or other control logic. In the illustrated example, processor 704 is connected to a bus 702, although any communication medium can be used to facilitate interaction with other components of computing module 700 or to communicate externally.

Computing module 700 might also include one or more memory modules, simply referred to herein as main memory 708. For example, preferably random access memory (RAM) or other dynamic memory, might be used for storing information and instructions to be executed by processor 704. Main memory 708 might also be used for storing temporary variables or other intermediate information during execution of instructions to be executed by processor 704. Computing module 700 might likewise include a read only memory (“ROM”) or other static storage device coupled to bus 702 for storing static information and instructions for processor 704.

The computing module 700 might also include one or more various forms of information storage mechanism 710, which might include, for example, a media drive 712 and a storage unit interface 720. The media drive 712 might include a drive or other mechanism to support fixed or removable storage media 714. For example, a hard disk drive, a floppy disk drive, a magnetic tape drive, an optical disk drive, a CD or DVD drive (R or RW), or other removable or fixed media drive might be provided. Accordingly, storage media 714 might include, for example, a hard disk, a floppy disk, magnetic tape, cartridge, optical disk, a CD or DVD, or other fixed or removable medium that is read by, written to or accessed by media drive 712. As these examples illustrate, the storage media 714 can include a computer usable storage medium having stored therein computer software or data.

In alternative embodiments, information storage mechanism 710 might include other similar instrumentalities for allowing computer programs or other instructions or data to be loaded into computing module 700. Such instrumentalities might include, for example, a fixed or removable storage unit 722 and an interface 720. Examples of such storage units 722 and interfaces 720 can include a program cartridge and cartridge interface, a removable memory (for example, a flash memory or other removable memory module) and memory slot, a PCMCIA slot and card, and other fixed or removable storage units 722 and interfaces 720 that allow software and data to be transferred from the storage unit 722 to computing module 700.

Computing module 700 might also include a communications interface 724. Communications interface 724 might be used to allow software and data to be transferred between computing module 700 and external devices. Examples of communications interface 724 might include a modem or softmodem, a network interface (such as an Ethernet, network interface card, WiMedia, IEEE 802.XX or other interface), a communications port (such as for example, a USB port, IR port, RS232 port Bluetooth® interface, or other port), or other communications interface. Software and data transferred via communications interface 724 might typically be carried on signals, which can be electronic, electromagnetic (which includes optical) or other signals capable of being exchanged by a given communications interface 724. These signals might be provided to communications interface 724 via a channel 728. This channel 728 might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to media such as, for example, memory 708, storage unit 720, media 714, and channel 728. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing module 700 to perform features or functions of the present invention as discussed herein.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. A system for voltage transformation, comprising:
a transformer module, the transformer module comprising a transformer core, a first set of windings, and a second set of windings;
a housing enclosing the transformer module; and
a cold plate, the cold plate configured to be thermally coupled to the interior of the housing.

2. The system of claim 1, wherein the cold plate is mounted to a surface of the housing.

3. The system of claim 1, further comprising a set of conduits, wherein one end of each conduit coupled to cold plate and the other end coupled to the housing.

4. The system of claim 1, further comprising a set of interfaces, the set of interfaces disposed on the surface of the housing.

5. The system of claim 4, wherein a subset of the set of interfaces are coupled to the first set of windings.

6. The system of claim 5, wherein the first set of windings have a set of taps and an interface of the subset of interfaces is coupled to a tap of the set of taps.

7. The system of claim 6, wherein the tap of the set of taps is coupled to ground.

8. The system of claim 4, further comprising a voltage sensor coupled to the transformer module, wherein an interface of the set of interfaces is coupled to the voltage sensor.

9. The system of claim 4, further comprising a current sensor coupled to the transformer module, wherein an interface of the set of interfaces is coupled to the current sensor.

10. The system of claim 4, further comprising a temperature sensor, wherein an interface of the set of interfaces is coupled to the temperature sensor and the temperature sensor measures an ambient temperature of the transformer module.

11. The system of claim 4, further comprising a temperature sensor, wherein an interface of the set of interfaces is coupled to the temperature sensor, the housing contains coolant, and the temperature sensor measures the temperature of the coolant.

12. The system of claim 1, further comprising an electronic module comprising a second housing, the electronic module configured to be mounted to the cold plate.

13. The system of claim 12, wherein the electronic module comprises a voltage sensor configured to be coupled to the transformer module, a current sensor configured to be coupled to the transformer module, and a temperature sensor configured to be coupled to the transformer module.

14. The system of claim 13, wherein the electronic module further comprises a processing module and a communication module, the electronic module and the communication module are coupled to the voltage sensor, the current sensor, and the temperature sensor.

15. The system of claim 14, wherein the electronic module comprises a converter configured to be coupled to the transformer module, the converter comprises a set of switches, and the processing module is configured to regulate the set of switches.

16. The system of claim 15, wherein the first set of windings have a set of taps and the converter is across the set of taps.

17. The system of claim 16, wherein a tap of the set of taps is coupled to ground.

18. The system of claim 15, wherein the electronic module comprises a fail-normal switch coupled across the converter and to the ground.

19. The system of claim 14, wherein the processing module is configured to determine an apparent power and a real power of the transformer module.

20. The system of claim 14, wherein the processing module is configured to determine a loading level of the transformer module.
